(19) United States
(12) Patent Application Publication
(10) Pub. No.: US 2008/0227265 A1
(43) Pub. Date: Sep. 18, 2008

(54) Methods for Fabricating Semiconductor Devices

(76) Inventor: HAK DONG KIM, Suwon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/131,016

(22) Filed: May 30, 2008

Related U.S. Application Data
(62) Division of application No. 10/944,115, filed on Sep. 17, 2004.

(30) Foreign Application Priority Data
Sep. 18, 2003 (KR) 10-2003-0064913
Sep. 18, 2003 (KR) 10-2003-0064914
Sep. 18, 2003 (KR) 10-2003-0064915

(51) Int. Cl. H01L 21/30

(52) U.S. Cl. 438/423; 257/E21.211

(57) ABSTRACT

Methods of fabricating a gate-insulating layer of a dual-gate semiconductor device are disclosed. A disclosed method comprises sequentially forming a buffer oxide layer and a nitride layer on a semiconductor substrate having at least one high voltage device area and at least one low voltage device area; forming at least one trench by selectively removing at least one portion of the buffer oxide layer, the nitride layer and the semiconductor substrate; forming at least one device isolation layer by depositing an oxide layer in the trench and planarizing the oxide layer; removing the nitride layer and the buffer oxide layer remaining on the high voltage device area; forming a first gate-insulating layer on the high voltage device area; removing the nitride layer and the buffer oxide layer remaining on the low voltage device area; and forming a second gate-insulating layer on the low voltage device area.

### CROSS REFERENCE TO RELATED APPLICATIONS

This application is a divisional of U.S. application Ser. No. 10/944,115, filed Sep. 17, 2004, which claims the benefit of Korean Patent Application Serial No. 10-2003-0064913, which was filed on Sep. 18, 2003, Korean Patent Application Serial No. 10-2003-0064914, which was filed on Sep. 18, 2003, and Korean Patent Application Serial No. 10-2003-0064915, which was filed on Sep. 18, 2003, all of which are hereby incorporated by reference in their entirety.

### FIELD OF THE DISCLOSURE

The present disclosure relates generally to semiconductor devices and, more specifically, to methods of fabricating semiconductor devices.

### BACKGROUND

A complementary metal oxide semiconductor (CMOS) device generally employs a thermal oxide, (for example, a rapid growing silicon oxide), as a gate-insulating layer. Recently, the thickness of the gate-insulating layer has been reduced below between 25 Å and 30 Å, which is a limit with respect to direct tunneling through the silicon oxide. Thus, as the thickness of the gate-insulating layer is reduced (e.g., due to increased integration of the semiconductor device), the static power consumption of the corresponding semiconductor device increases due to a rise of the off current caused by direct tunneling. This increased power consumption has a negative effect on device operation.

On the other hand, a display panel of a TFT-LCD (thin film transistor—liquid crystal display) or a portable display device generally comprises a driver IC (integrated circuit). Such a driver IC typically uses a dual-gate semiconductor device in which a high voltage device and a low voltage device are formed together on the same semiconductor substrate. In such an instance, the gate-insulating layer of the dual-gate semiconductor device has a different thickness on the high voltage device then on the low voltage device.

Twu et al., U.S. Pat. No. 6,706,577, describes a method of simultaneously forming different gate oxide layers for high voltage and low voltage transistors using a two-step wet oxidation process. The method described in the Twu et al. patent comprises wet-oxidizing the surface of a semiconductor substrate to form a first gate oxide layer in the active areas while the low voltage active area is covered with a mask, and thereafter wet-oxidizing the surface of the semiconductor substrate without the mask to form a second gate oxide layer on the first gate oxide layer in the high voltage active area.

Mukhopadhyay et al., U.S. Pat. No. 6,399,448, describes a method for forming a multiple thickness gate oxide layer. The described method comprises implanting nitrogen ions into a first area of a semiconductor substrate while a second area of the semiconductor substrate is masked, implanting argon ions into the second area of the semiconductor substrate while the first area of the semiconductor substrate is masked, and thermally growing a gate oxide layer wherein the oxide growth is retarded in the first area and enhanced in the second area.

FIGS. 1a through 1d are cross-sectional views illustrating a conventional process of fabricating a gate-insulating layer of a dual-gate semiconductor device. Referring to FIG. 1a, a semiconductor substrate 101 having at least one high voltage device area and at least one low voltage device area is prepared. A first insulating layer is deposited over the semiconductor substrate 101. The first insulating layer is used as an etching mask to form at least one trench 104. The first insulating layer generally comprises an oxide layer 102 and a nitride layer 103. A mask pattern (not shown) is formed over the first insulating layer through a photolithography process. Using the mask pattern, the first insulating layer and the semiconductor substrate 101 are selectively etched to form the trench 104.

Referring to FIG. 1b, a second insulating layer is deposited over the semiconductor substrate 101 so as to completely fill the trench 104. The second insulating layer is preferably an oxide layer. The second insulating layer is planarized by a chemical mechanical polishing (hereinafter referred to as “CMP”) process or an etch back process to complete at least one device isolation layer 105.

Referring to FIG. 1c, a first gate-insulating layer 106 for the high voltage device is formed on the structure of FIG. 1b by a first thermal oxidation process. Next, the portion of the first gate-insulating layer 106 positioned on the low voltage device area is removed through a photolithography process. The first gate-insulating layer has a thickness between 50 Å and 150 Å. The first thermal oxidation process is performed in a nitrogen monoxide (hereinafter referred to as “NO”) atmosphere, so that the first gate-insulating layer can be made into an oxide nitride layer.

Referring to FIG. 1d, a second gate-insulating layer 107 for the low voltage device is formed on the resulting semiconductor substrate 101 by a second thermal oxidation process. In the illustrated example, the second gate-insulating layer 107 is only formed on the low voltage device area. The second gate-insulating layer 107 has a thickness between 20 Å and 30 Å. The second thermal oxidation process is performed in a NO atmosphere so that the second gate-insulating layer can become an oxide nitride layer.

In the above-described method for fabricating the gate-insulating layer of a dual-gate semiconductor device, the semiconductor substrate is exposed twice (i.e., once when the first insulating layer is completely removed from the surface of the substrate by an etching process after the formation of the device isolation layer, and a second time when the first gate insulating layer on the low-voltage device area is removed by an etching process to form the first gate-insulating layer on only the high voltage device area). These repetitive etching processes may cause damage to the semiconductor substrate, thereby inducing a loss of ions and adjusting the threshold voltage and the leakage current of the resulting device due to the partial loss of the edge of the device isolation layer.

Furthermore, although the thermal oxidation processes are performed in the NO atmosphere to increase the dielectric constant of the first and second gate-insulating layers, the proportion of nitrogen which penetrates into the first and second gate-insulating layers is very low.

### BRIEF DESCRIPTION OF THE DRAWINGS

FIGS. 1a through 1d are cross-sectional views illustrating a conventional process of fabricating a gate-insulating layer of a dual-gate semiconductor device.

FIGS. 2a through 2e are cross-sectional views illustrating an example process of fabricating a gate-insulating layer of a dual-gate semiconductor device performed in accordance with the teachings of the present invention.

FIG. 3 and FIG. 4 are cross-sectional views illustrating an example process for implanting ions into a semiconductor substrate performed in accordance with additional teachings of the present invention.

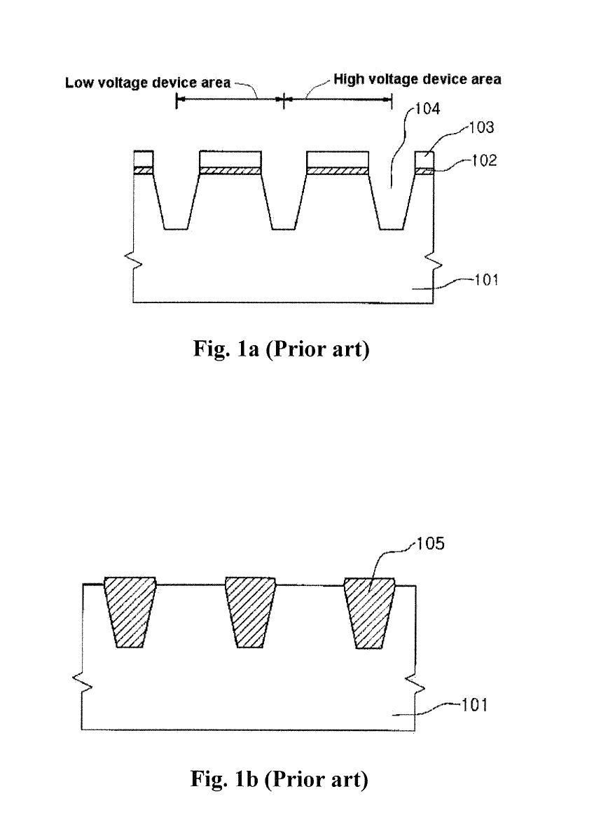

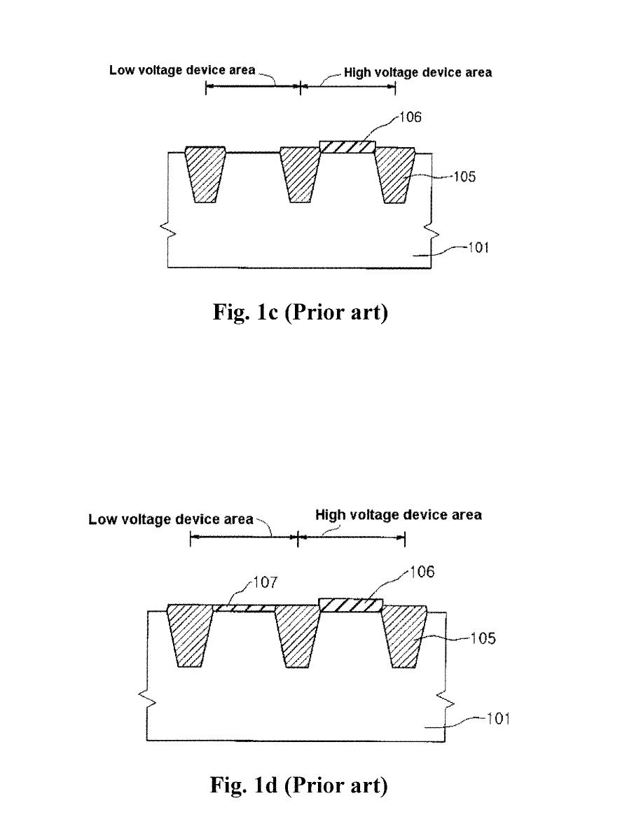

### DETAILED DESCRIPTION

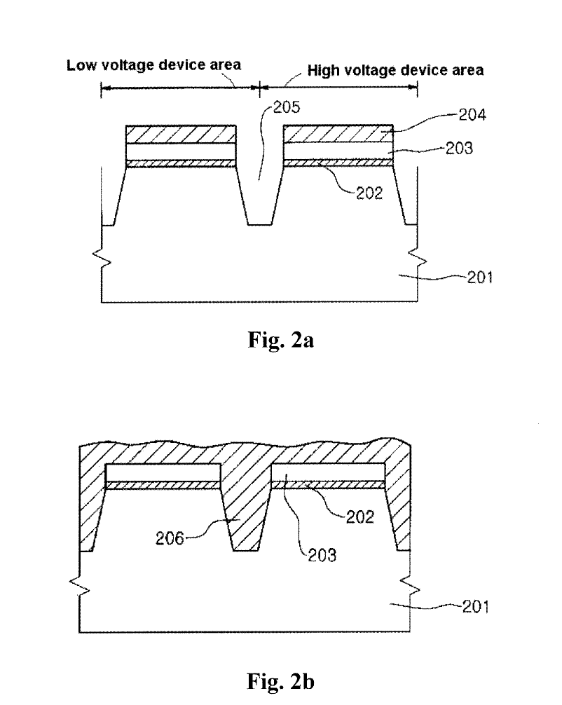

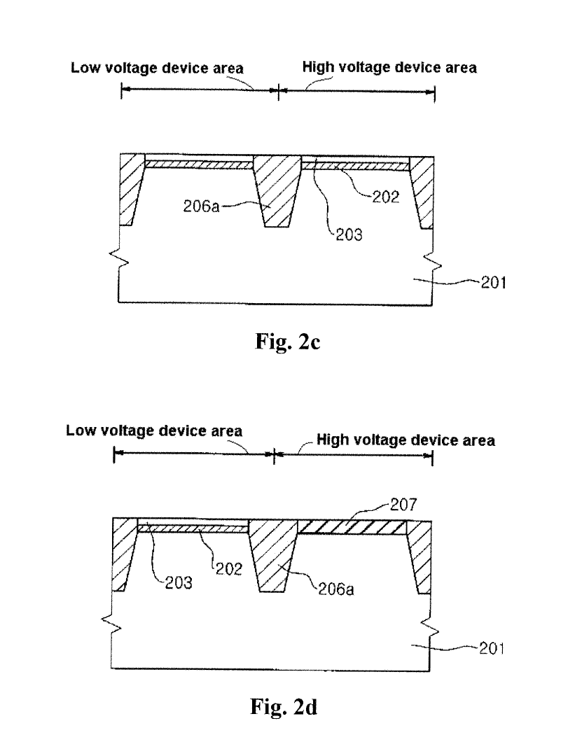

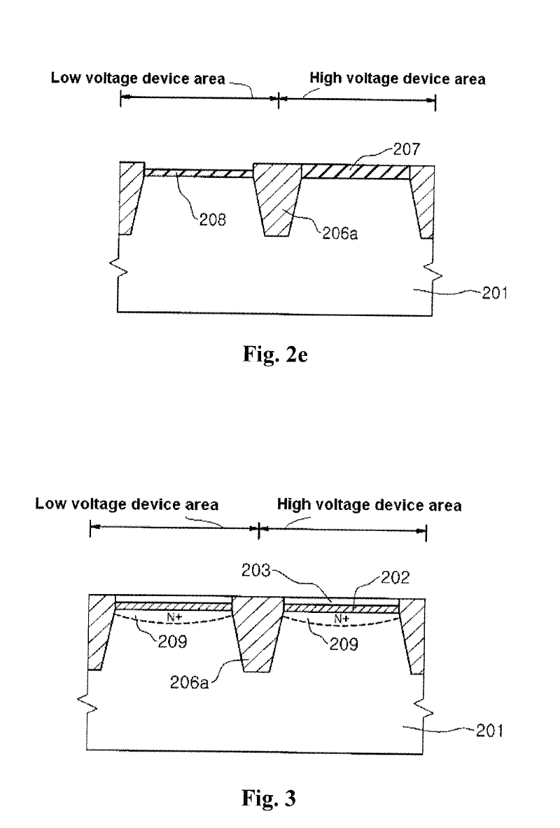

FIGS. 2a through 2e are cross-sectional views illustrating an example process of fabricating a gate-insulating layer of a dual-gate semiconductor device. Referring to FIG. 2a, a semiconductor substrate 201 having at least one high-voltage device area and at least one low-voltage device area is prepared. A buffer oxide layer 202 is formed on the surface of the semiconductor substrate 201 through a thermal oxidation process. A nitride layer 203 is then deposited over the entire surface of the semiconductor substrate 201 including the buffer oxide layer 202 by a chemical vapor deposition process. The buffer oxide layer 202 and the nitride layer 203 play a role as an etching mask in a later trench formation process. The buffer oxide layer 202 preferably has a thickness of between about 40 Å and about 150 Å. The nitride layer 203 preferably has a thickness of between about 600 Å and about 1500 Å.

Next, a photoresist layer is deposited over the nitride layer 203. Some portion(s) of the photoresist layer are removed through a photolithography process to form a mask pattern 204. The nitride layer 203 and the buffer oxide layer 202 are then etched while using the mask pattern 204 as a mask. The portion(s) of the semiconductor substrate 201 which are exposed by the removal of the nitride layer 203 and the buffer oxide layer 202 are etched and removed by a predetermined amount. Thus, at least one trench 205 is formed in the semiconductor substrate 201.

Referring to FIG. 2b, the mask pattern 204 is removed. An insulating layer 206 is deposited over the resulting semiconductor substrate 201 so as to completely fill the trench 205. The insulating layer 206 is preferably an oxide layer.

Referring to FIG. 2c, the insulating layer 206 is planarized by a CMP process. As a result, at least one device isolation layer 206a is formed in the semiconductor substrate 201. In the example shown in FIG. 2c, the surface of the device isolation layer 206a is at a higher level than the surface of the semiconductor substrate 201. In other words, portions of the nitride layer 203 and the buffer oxide layer 202 remain on the semiconductor substrate 201 after completion of the CMP process. The processes disclosed herein take advantage of the remaining nitride layer 203. The remaining nitride layer 203 has a predetermined thickness.

Referring to FIG. 2d, the portion(s) of the nitride layer 203 and the buffer oxide layer 202 remaining on the high voltage device area are removed by photolithographic and etching processes. For instance, in the illustrated example the nitride layer 203 is removed by a wet etching process using a mixture solution of purified water and phosphoric acid (H₃PO₄). The buffer oxide layer 203 is removed by using dilute HF (DHF). Next, a first gate-insulating layer 207 is formed on the high voltage device area through a first thermal oxidation process. The first thermal oxidation process is performed for about 15 to 30 minutes in a NO atmosphere at a temperature between about 850° C. and 900° C. The thickness of the first gate-insulating layer 207 is between about 50 Å and 150 Å.

Referring to FIG. 2e, the remaining nitride layer 203 and the buffer oxide layer 202 on the low voltage device area are removed by the same photolithographic and etching processes as were used to remove the remaining nitride layer 203 and the buffer oxide layer 202 on the high voltage device area. Next, a second thermal oxidation process is performed to form a second gate-insulating layer 208 on the low voltage device area. The second thermal oxidation process is preferably carried out for about 5 to about 15 minutes in a NO atmosphere at a temperature between about 850° C. and about 900° C. The second gate-insulating layer 208 has a thickness of between about 20 Å and about 30 Å.

In other example processes performed in accordance with the teachings of the present invention, an ion implantation process is performed before the first gate-insulating layer and the second gate-insulating layer are formed on the high voltage device area and the low voltage device area, respectively. Referring to the example of FIG. 3, a nitrogen ion implantation process is performed for the entire surface of the semiconductor substrate after the device isolation layer 206a is completed. Thus, a nitrogen ion implantation layer 209 is formed under the surface of the semiconductor substrate 201. The purpose of implanting nitrogen ions is to increase the proportion of a nitrogen component for the later thermal oxidation processes to form the gate-insulating layers. The nitrogen ions are implanted at a concentration between about 1E13 ions/cm² and about 1E14 ions/cm² at an energy level between about 5 keV and about 20 keV. The nitrogen ions implanted into the high voltage device area react with the semiconductor substrate 201 during the first thermal oxidation process to form the first gate-insulating layer with an abundance of nitride. The nitrogen ions implanted into the low voltage device area react with the semiconductor substrate 201 during the second thermal oxidation process to form the second gate-insulating layer with an abundance of nitride.

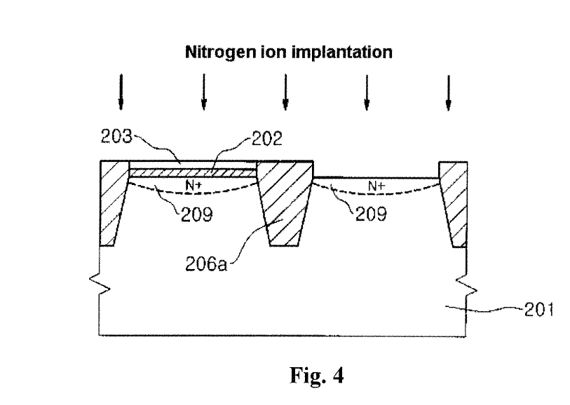

In other example processes performed in accordance with the teachings of the present invention, the above-described ion implantation process is performed after the nitride layer 203 and the buffer oxide layer 202 on the high voltage device area are removed. In more detail, as shown in FIG. 4, after the device isolation layer 206a is completed, the nitride layer 203 and the buffer oxide layer 202 on the high voltage device area are removed. A nitrogen ion implantation process is then performed for the entire surface of the resulting semiconductor substrate 201. The nitrogen ions are implanted at a concentration between about 1E13 ions/cm² and about 1E14 ions/cm² at an energy level between about 5 keV and about 20 keV. Thus, a nitrogen ion implantation layer 209 is formed under the surface of the semiconductor substrate 201. In this example, the nitrogen ions are more deeply implanted into the high voltage device area on the semiconductor substrate 201 than into the low voltage device area, because the surface of the high voltage device area is directly exposed to the nitrogen ions. A reason for implanting nitrogen ions more deeply into the high voltage device area is that the first gate-insulating layer on the high voltage device area requires a larger dielectric constant than the second gate-insulating layer on the low voltage device area. As a result, the first gate-insulating layer must have a larger thickness than the second gate-insulating layer.

From the foregoing, persons of ordinary skill in the art will appreciate that the processes disclosed herein selectively etch the buffer oxide layer 202 and nitride layer 203 on the high voltage device area and low voltage device area to form the first gate-insulating layer and the second gate-insulating layer, respectively. As a result, the above-described gate-insulating layer fabrication methods can prevent or reduce damage to the semiconductor substrate by minimizing the exposure of the semiconductor substrate. Moreover, by performing the nitrogen ion implantation process for the entire surface of the semiconductor substrate prior to forming the gate-insulating layers in order to increase the proportion of a nitrogen component in the gate-insulating layers to be formed in the later processes, the disclosed methods can increase the dielectric constant of the gate-insulating layers, thereby simplifying the fabricating process and improving the electric characteristics of the fabricated semiconductor device.

Although certain example methods, apparatus and articles of manufacture have been described herein, the scope of coverage of this patent is not limited thereto. On the contrary, this patent covers all methods, apparatus and articles of manufacture fairly falling ally or under the doctrine of equivalents.

What is claimed is:

1. A method of fabricating a semiconductor device comprising:
sequentially forming a buffer oxide layer and a nitride layer on a semiconductor substrate having at least one high voltage device area and at least one low voltage device area;
forming at least one trench by selectively removing at least one portion of the buffer oxide layer, the nitride layer and the semiconductor substrate;
depositing an oxide layer in the trench and planarizing the oxide layer;
performing a nitrogen ion implantation on an entire surface of the semiconductor substrate;
removing the nitride layer and the buffer oxide layer remaining on the high voltage device area;
forming a first gate-insulating layer on the high voltage device area;
removing the nitride layer and the buffer oxide layer remaining on the low voltage device area; and
forming a second gate-insulating layer on the low voltage device area.

2. The method as defined in claim 1, wherein the nitrogen ion implantation is performed before the nitride layer and the buffer oxide layer are removed from either the high voltage device area or the low voltage device area.

3. The method as defined in claim 1, wherein the nitrogen ion implantation is performed after the nitride layer and the buffer oxide layer are removed from the high voltage device area and before the first gate-insulating layer is formed on the high voltage device area.

4. The method as defined in claim 1, wherein the nitrogen ions are implanted into the semiconductor substrate at a concentration between about 1E13 ions/cm² and about 1E14 ions/cm² at an energy level between about 5 keV and about 20 keV.

5. The method as defined in claim 1, wherein the buffer oxide layer has a thickness between about 40 Å and about 150 Å and the nitride layer has a thickness between about 600 Å and about 1500 Å.

6. The method as defined in claim 1, wherein removing the nitride layer and the buffer oxide layer remaining on the high voltage device area comprises wet-etching the nitride layer with a mixture of purified water and phosphoric acid, and removing the buffer oxide layer with dilute HF.

7. The method as defined in claim 1, wherein the first gate-insulating layer has a thickness between about 50 Å and about 150 Å, and the second gate-insulating layer has a thickness between about 20 Å and about 30 Å.

8. The method as defined in claim 1, wherein the first gate-insulating layer is formed by heat-treating the semiconductor substrate for about 15 to about 30 minutes in a NO atmosphere at a temperature between about 850° C. and about 900° C.

9. The method as defined in claim 1, wherein the second gate-insulating layer is formed by heat-treating the semiconductor substrate for about 5 to about 15 minutes in a NO atmosphere at a temperature between about 850° C. and about 900° C.

10. The method as defined in claim 1, wherein the forming the first gate-insulating layer is performed next to the removing the nitride layer and the buffer oxide layer.

11. The method as defined in claim 1, wherein the first gate-insulating layer is formed in direct contact with the high voltage device area.

12. The method as defined in claim 1, wherein the first gate-insulating layer is oxide nitride.
